(19) United States
(12) Patent Application Publication
(10) Pub. No.: US 2024/0353696 A1
(43) Pub. Date: Oct. 24, 2024

(54) Optical Modulator and Optical Transmitter

(71) Applicant: Nippon Telegraph and Telephone Corporation, Tokyo (JP)

(72) Inventors: Meishin Chin, Musashino-shi, Tokyo (JP); Takahiko Shindo, Musashino-shi, Tokyo (JP); Shigeru Kanazawa, Musashino-shi, Tokyo (JP)

(21) Appl. No.: 18/682,391

(22) PCT Filed: Aug. 12, 2021
(86) PCT No.: PCT/JP2021/029775

§ 371 Date: Feb. 8, 2024

(51) Int. Cl. G02F 1/017; H01S 5/026

(52) U.S. Cl. CPC G02F 1/01708; H01S 5/0265; G02F 2201/063; G02F 2202/101; G02F 2202/102; G02F 2202/108

(57) ABSTRACT

An EA modulator having a structure in which an increased optical confinement factor is provided. An optical modulator having a high-mesa structure made of an InP-based materials, including: a waveguide core having a multi quantum well structure; a lower selective etching layer inserted into a lower cladding at an interval from the waveguide core; and an upper selective etching layer inserted into an upper cladding at an interval from the waveguide core, where the lower selective etching layer and the upper selective etching layer are narrower than a mesa width of the high-mesa structure.

### TECHNICAL FIELD

The present invention relates to optical modulators and optical transmitters, and more particularly, to an optical transmitter which is used in the field of optical communication and in which a light source and an optical modulator are monolithically integrated.

### BACKGROUND ART

In the field of optical communication, it is desired to improve a communication speed more than ever due to the spread of video and moving image distribution or the like through a network. An optical transmitter for transmitting an output of a semiconductor laser (LD: Laser Diode) to which an intensity modulator is added is small-sized and low-cost, and is used as a practical light source. In this way, widening of the band of an Electro-absorption Modulated Laser (EML) in which a semiconductor laser and an optical modulator are monolithically integrated has been an important issue. For example, in a NPL 1, there has been proposed a technique of expanding the band by replacing the semiconductor cladding of the modulator portion of the EML with a polymeric material having a lower dielectric constant.

Conventionally, in order to widen the band of an Electro-Absorption (EA) modulator, a hybrid waveguide structure in which buried semiconductors in the EA modulator are removed, that is, so-called high-mesa structure has been proposed. Although the high-mesa structure can enhance optical confinement in the horizontal direction of the waveguide cross section. The EA modulator made of an InP-based material has a small refractive index difference and has a problem that it is difficult to improve the optical confinement factor in the vertical direction.

Further, the EML is a monolithically integrated element in which different waveguide structures are joined, and even if the core materials are the same, the cladding materials are different. In such a structure, since propagation characteristics of fundamental modes in the respective waveguides are different, there is a problem in which optical loss is caused by light reflection and scattering at the junction point, as a result the output power of the optical transmitter is reduced.

### CITATION LIST

### Non Patent Literature

[NPL 1] W. Kobayashi et al., “Low-Power Consumption 28-Gb/s 80-km Transmission With 1.3-μm SOA-Assisted Extended-Reach EADFB Laser,” in Journal of Lightwave Technology, vol. 35 No. 19, pp. 4297-4303, 1 Oct.1, 2017 doi: 10.1109/JLT.2017.2737626.

### SUMMARY OF INVENTION

An object of the present invention is to provide an EA modulator having a structure that increases optical confinement factor, and a high-output optical transmitter having a structure that reduces junction loss in an optical connection between different types of waveguides made of different cladding materials.

In order to achieve such an object of the present invention, an embodiment of the optical modulator has a high-mesa structure made of an InP-based materials, and includes: a waveguide core having a multi quantum well structure; a lower selective etching layer inserted into a lower cladding at an interval from the waveguide core; and an upper selective etching layer inserted into an upper cladding at an interval from the waveguide core, where width of the lower selective etching layer and the upper selective etching layer are narrower than a mesa width of the high-mesa structure.

Further, an embodiment of the optical transmitter is monolithically integrated by: a buried semiconductor laser filled with insulating InP; an optical modulator having a high-mesa structure made of an InP-based materials; and a connecting region connecting a waveguide core of the semiconductor laser and a waveguide core of the optical modulator, where the connecting region is made of a bulk waveguide composed of an InP-based material, and includes a semiconductor buried taper portion that is a connecting portion with the waveguide core of the semiconductor laser, where the semiconductor buried taper portion is filled with the insulating InP at a connecting end face with the waveguide core of the semiconductor laser, and filled with a buried layer that buries the waveguide core of the optical modulator at a connecting end face with the waveguide core of the optical modulator, where a tapered buried interface forms 45-degrees with respect to an optical axis direction of the bulk waveguide.

### BRIEF DESCRIPTION OF DRAWINGS

FIG. 1 is a diagram showing a configuration of an optical transmitter according to an embodiment 1 of the present invention.

FIG. 2 shows a method of manufacturing an optical transmitter of the embodiment 1.

FIG. 3 shows mesa width dependency of an optical confinement factor in an EA modulator.

FIG. 4 shows dependence of an optical confinement factor on an interval between a waveguide core and a selective etching layer in an EA modulator of an embodiment 1.

FIG. 5 is a diagram showing a configuration of an optical transmitter according to an embodiment 2 of the present invention.

FIG. 6 shows a semiconductor buried taper portion of a connecting region in an EA modulator of an embodiment 1.

FIG. 7 is a diagram showing a configuration of an optical transmitter according to an embodiment 3 of the present invention.

FIG. 8 is a diagram showing dependence of an optical coupling coefficient on an interval between a waveguide core and a selective etching layer in an EA modulator of an embodiment 3.

### DESCRIPTION OF EMBODIMENTS

Embodiments of the present invention will be described in detail below with reference to the drawings. In the present embodiment, an EML in which a Distributed FeedBack (DFB) semiconductor laser and an EA modulator are integrated is described as an example, but the present invention can be applied to an optical transmitter using a light source such as a Distributed Bragg Reflector (DBR) semiconductor laser or using an optical modulator of another system.

### Embodiment 1

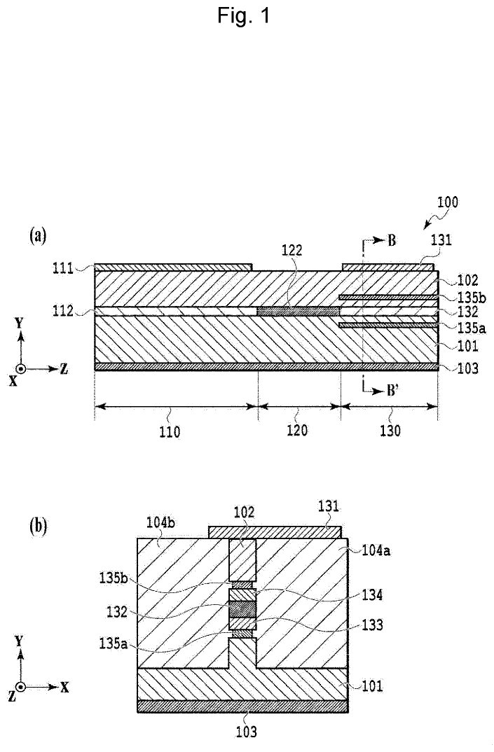

FIG. 1 shows a configuration of an optical transmitter according to the embodiment 1 of the present invention. FIG. 1(a) is a cross-sectional view of a waveguide core in an optical axis (Z-axis) direction, and FIG. 1(b) is a cross-sectional (XY-plane) view perpendicular to the optical axis of an EA modulator. In the optical transmitter 100, the waveguide cores 112, 122, and 132 and the p-InP cladding 102 to be an upper cladding are laminated on the n-InP substrate 101 also serving as a lower cladding. The optical transmitter 100 has a configuration in which the DFB laser 110 and the EA modulator 130 are connected by the connecting region 120. The common lower face electrode 103 is formed on the lower face of the n-InP substrate 101, the LD electrode 111 is formed on the upper face of the DFB laser 110, and the EA electrode 131 is formed on the upper face of the EA modulator 130. The DFB laser 110 is a buried semiconductor laser filled with an insulating InP doped with impurity such as Fe.

Referring to FIG. 1(b), a configuration of the EA modulator 130 having a high-mesa structure made of the InP-based materials will be described in detail. The waveguide core 132 has, for example, a Multi Quantum Well (MQW) structure made of InGaAsP-based materials. A part of the n-InP substrate 101, the waveguide core 132 and the p-InP cladding 102 are processed into a high-mesa structure, and both side faces of the mesa are filled with the buried layers 104a, 104b such as a polymeric material having a low refractive index, for example, benzocyclobutene (BCB). The buried layers 104a, 104b contribute to an improvement of the optical confinement factor and a reduction of a capacitance of an electrode pad of the EA modulator. By the way, the mesa may be protected by passivation film processing such as SiO₂, SiN or the like without filling the high-mesa structure with the polymer or semiconductor material. In this case, the buried layers 104a, 104b in FIG. 1(b) can be regarded as air.

The lower selective etching layer 135a is inserted into the n-InP substrate 101 of the waveguide core 132 at an interval from the waveguide core 132. The lower selective etching layer 135a is composed of a different composition in etching rate with respect to a semiconductor material of the waveguide core such as InP, for example, of a material such as InGaAlAs with respect to InP, InGaAsP. Similarly, the upper selective etching layer 135b is inserted into the upper cladding at an interval from the waveguide core 132. Each of widths of the selective etching layers 135a, 135b i.e., a width in the X-axis direction is processed so as to become narrower than the width of the mesa. With such a structure, the effective refractive index of the cladding region can be reduced, and the optical confinement factor in the Y-axis direction can be improved.

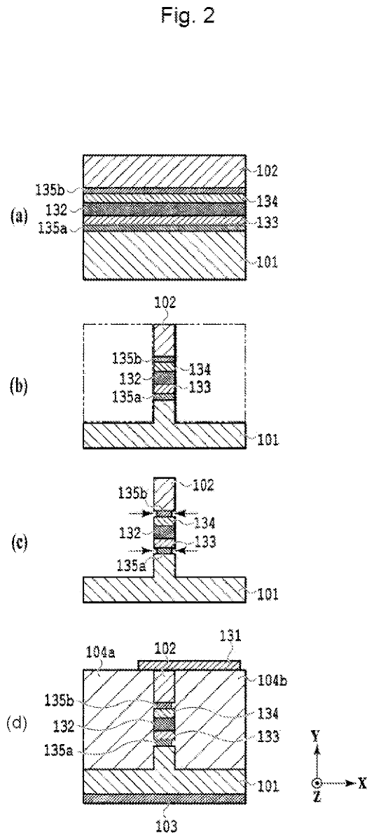

FIG. 2 schematically shows a method of manufacturing the EA modulator 130 of the optical transmitter of the embodiment 1. The selective etching layer 135a, lower cladding layer 133, waveguide core 132, upper cladding layer 134, selective etching layer 135b, and p-InP cladding 102 are sequentially laminated on the n-InP substrate 101 by epitaxial growth such as MOCVD (FIG. 2(a)). A material of the waveguide core 132 is desirable to be an InGaAsP material having a band gap corresponding to a wavelength in 1.3 to 1.6 μm for an application of the optical communication field. Next, the respective layers are removed by etching process until reaching a part of the n-InP substrate 101, and a high-mesa structure having a desired width in the X-axis direction is formed (FIG. 2(b)). In this case, dry etching is performed by an RIE (Reactive Ion Etching) apparatus or an ICP (Inductively coupled Plasma) apparatus.

Next, etching process is selectively applied to the selective etching layers 135a, 135b made of the InGaAlAs material by wet etching using an etchant (FIG. 2(c)). Finally, both sides of the high-mesa structure are filled with a polymeric material such as BCB to form the buried layers 104a, 104b, and the lower face electrode 103 and the EA electrode 131 are formed (FIG. 2(d)).

The film thickness of each layer is 240 nm for the waveguide core 132, 450 nm for the selective etching layers 135a, 135b, and 200 nm for the lower cladding layer 133 and the upper cladding layer 134. When the mesa width of the high-mesa structure is 1 μm, the amount of side etching in the etching process shown in FIG. 2(c) is controlled within a range in 200 to 300 nm. If the amount of side etching is too large, the width of the waveguide in the X direction in the selective etching layer becomes narrow, and electric resistance becomes high, which leads to a decrease in thermal conductivity. Each of the widths of the selective etching layers 135a, 135b is preferably within a range of 30 to 50% with respect to the mesa width.

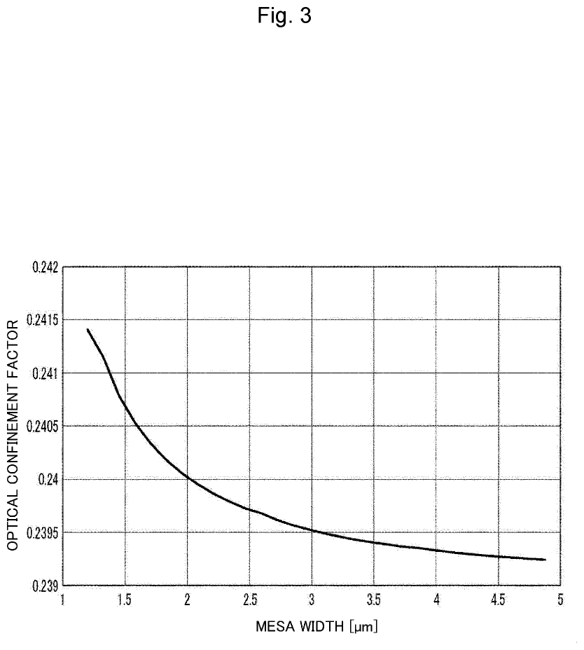

FIG. 3 shows the mesa width dependency of the optical confinement factor in the EA modulator. The EA modulator of a conventional structure not including a selective etching layer is shown. The narrower the mesa width of the high-mesa structure, the better the optical confinement factor, but the mesa width should be set to about 1.2 μm in consideration of a dimension error in manufacturing and accuracy of a mesa form. In this case, the optical confinement factor is about 0.241.

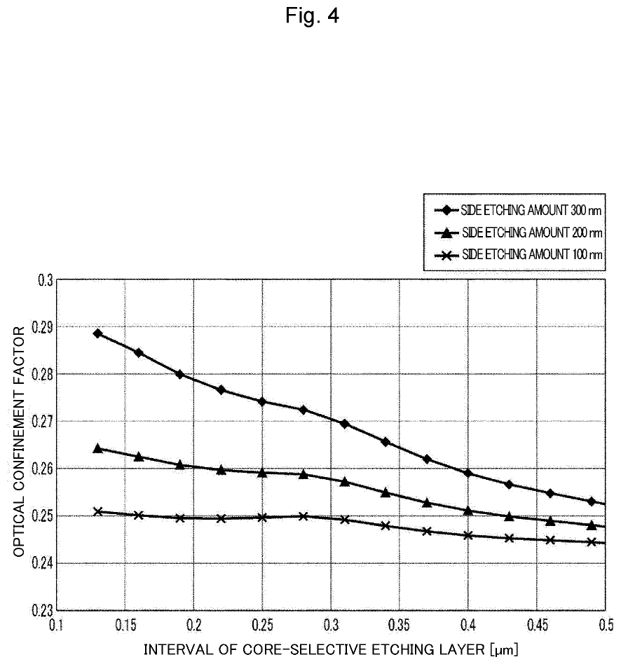

FIG. 4 shows dependence of the optical confinement factor on an interval between the waveguide core and the selective etching layer in the EA modulator of the embodiment 1. When the mesa width of the high-mesa structure is 1.2 μm, the optical confinement factor varies depending on the interval between the waveguide core and the respective lower and upper selective etching layers, i.e., thicknesses of the lower cladding layer 133 and upper cladding layer 134. The three graphs represent the case where the amounts of side etching are different from each other. When the amount of side etching is 300 nm, and the interval between the waveguide core and the selective etching layer is 0.2 μm, the optical confinement factor becomes 0.28. The optical confinement factor can be improved by 13% as compared with the EA modulator of the conventional structure. By the way, when the amount of side etching is 100 nm, it is understood that the improvement of the optical confinement factor is difficult to obtain regardless of the interval between the waveguide core and the selective etching layer.

As described above, it is desirable that the interval between the waveguide core and the selective etching layer, that is, the thicknesses of the lower cladding layer 133 and the upper cladding layer 134, be as thin as possible. Since the mode field diameter of the propagation mode in the conventional structure is about 0.6 μm (FWHM), the effect of improving the optical confinement factor cannot be obtained at a thickness of 1 μm or more, because the selective etching layer and the propagation mode hardly overlap with each other. Therefore, the interval between the waveguide core and the selective etching layer is desirable to be a range of 0.01 to 1 μm.

Further, when the thicknesses of the selective etching layers 135a, 135b are a range of 0.2 to 1 μm, an increase of 5% or more of the optical confinement factor is observed by a result of a simulation, thus it is desirable to fall within this range.

### Embodiment 2

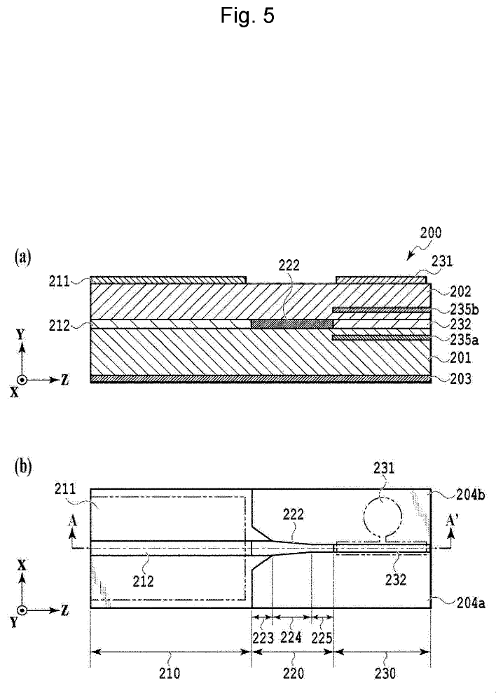

FIG. 5 shows a configuration of an optical transmitter according to an embodiment 2 of the present invention. FIG. 5(a) is a cross-sectional view of the high-mesa structure in an optical axis (Z-axis) direction, and FIG. 5(b) is a perspective view viewed from the top. The optical transmitter 200 has a configuration in which the DFB laser 210 and the EA modulator 230 are connected by the connecting region 220. In the optical transmitter 200, the waveguide cores 212, 222, and 232 and the p-InP cladding 202 to be an upper cladding are laminated on the n-InP substrate 201 also serving as a lower cladding. The common lower face electrode 203 is formed on the lower face of the n-InP substrate 201, the LD electrode 211 is formed on the upper face of the DFB laser 210, and the EA electrode 231 is formed on the upper face of the EA modulator 230. The EA modulator 230 of the optical transmitter 200 has a high-mesa structure like in the embodiment 1 and is filled with the buried layers 204a, 204b.

In the embodiment 2, the waveguide core 222 in the connecting region 220 is a bulk waveguide made of an InGaAsP-based material. The DFB laser 210, the connecting region 220 and the EA modulator 230 have different layer structures and are manufactured by epitaxial growth for a three-time. The respective regions are connected by a waveguide connection through a technique called butt joint. The connecting region 220 includes: a semiconductor buried taper portion 223 which is a connecting portion with the DFB laser 210; a linear portion 225 which is a connecting portion with the EA modulator 230; and a passive taper portion 224 which connects both. By the way, the passive taper portion is omitted if the widths of the waveguide cores to be connected are the same. With such a structure, the connecting region 220 connects the waveguide core 212 of the DFB laser 210 and the waveguide core 232 of the EA modulator 230 with a low loss.

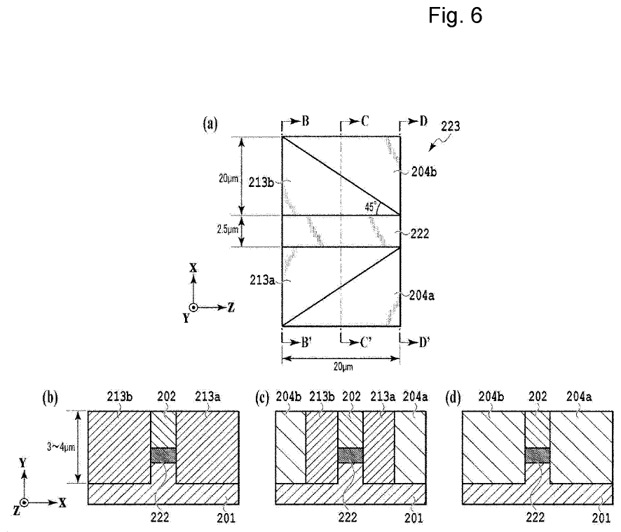

FIG. 6 shows a semiconductor buried taper portion of a connecting region in the EA modulator of the embodiment 2. FIG. 6(a) is a view of the semiconductor buried taper portion 223 of the connecting region 220 as viewed from the top. FIG. 6(b) is a cross-sectional view of a connecting end face with the DFB laser 210. The width of the mesa of the DFB laser 210, that is, the width of the waveguide core 212, is 2.5 μm. FIG. 6(d) is a cross-sectional view of a connecting end face with the passive taper portion 224. FIG. 6(c) is a cross-sectional view showing an intermediate portion between both of connecting portions.

As shown in FIG. 6(b), the waveguide core 222 is filled with the InP claddings 213a, 213b burying the waveguide core 212 of the DFB laser 210 near the connecting end face with the DFB laser 210. On the other hand, as shown in FIG. 6(d), the waveguide core 222 is filled with the buried layers 204a, 204b burying the waveguide core 232 of the EA modulator 230 near the connecting end face with the passive taper portion 224. As shown in FIG. 6(a), the tapered buried interface is processed to form 45 degrees with respect to the optical axis direction of the waveguide core.

As a result of the optical simulation, in the case of a connecting region without such a tapered buried structure, a coupling efficiency between the waveguide core 212 of the DFB laser 210 and the waveguide core 222 in the connecting region 220 is 0.955, on the other hand, a coupling efficiency is improved by 0.999 in the connecting region 220 having the semiconductor buried taper portion 223 of the embodiment 2.

The width of the mesa of the EA modulator 230, that is, the width of the waveguide core 232, is 1.2 μm. Therefore, the passive taper portion 224 is provided between the linear portion 225 connected to the waveguide core 232 and the semiconductor buried taper portion 223. The length of the passive taper portion 224 is set to be twice as long as that of the semiconductor buried taper portion 223, and is 40 μm. The length of the linear portion 225 is 20 μm. The DFB laser 210 has an element length of 300 μm, and the EA modulator 230 has an element length of 75 μm. With such a structure of the connecting region 220, a coupling efficiency between the waveguide core 212 of the DFB laser 210 and the waveguide core 232 of the EA modulator 230 is 0.96.

By the way, although the selective etching layers 235a, 235b are inserted into the EA modulator 230 in the same manner as in the embodiment 1, the effect of the connecting region 220 of the embodiment 2 can be obtained even in the EA modulator of the conventional structure.

### Embodiment 3

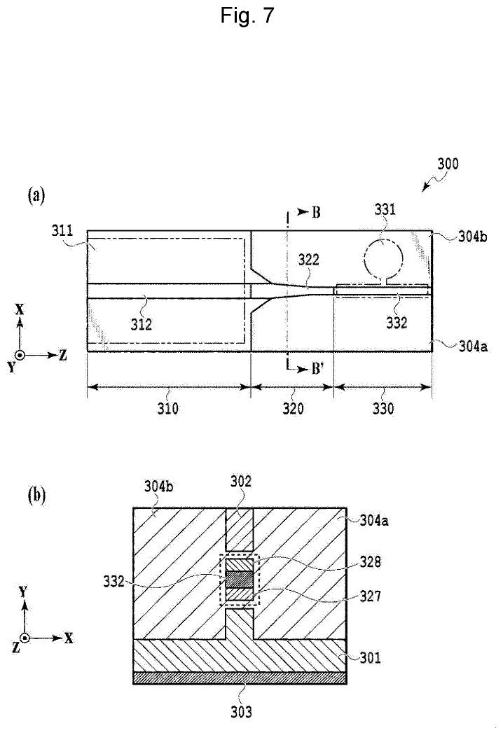

FIG. 7 shows a configuration of an optical transmitter according to an embodiment 3 of the present invention. FIG. 7(a) is a perspective view viewed from the top, and FIG. 7(b) is a cross-sectional (XY plane) view perpendicular to an optical axis of a waveguide core in a connecting region. The optical transmitter 300 has a configuration in which the DFB laser 310 and the EA modulator 330 are connected by the connecting region 320. In the connecting region 320 of the optical transmitter 300, the waveguide core 322 and the p-InP cladding 302 to be an upper cladding are laminated on the n-InP substrate 301 also serving as a lower cladding. The structures of the DFB laser 310 and the EA modulator 330 are the same as those of the embodiments 1, 2. The connecting region 320 has a bulk waveguide made of an InGaAsP-based material as the waveguide core 322, and includes the semiconductor buried taper portion, the passive taper portion and the linear portion as with the embodiment 2.

In the embodiment 3, a selective etching layer similar to that of the EA modulator 330 is introduced into the passive taper portion 324 and the linear portion 325 of the connecting region 320 to further improve the optical coupling efficiency between the elements. Since the connecting region 320 and the EA modulator 330 are manufactured by different epitaxial growth, different layer structures can be introduced. The difference between the selective etching layer of the connecting region 320 and the selective etching layer of the EA modulator 330 is in that the mesa is penetrated in the X-axis direction and filled with the buried layers 304a, 304b such as BCB which is a polymeric material having a low refractive index in the connecting region 320. That is, the selective etching layer made of the connecting region 320 can be replaced with the selective etching layer made of the polymeric material.

In embodiment 3, as in the manufacturing process shown in FIG. 2, first, a selective etching layer is laminated also in the connecting region 320. After the mesa is formed, etching process is performed twice before a process of being filled with the buried layers 304a, 304b. In the first wet etching process, the side face of the mesa of the EA modulator 330 is covered with a photomask and protected so that side etching is not subjected. That is, only the selective etching layer in the connecting region 320 is etched. In the second wet etching process, the protective mask is removed, and the selective etching layers of both the connecting region 320 and the EA modulator 330 are etched. In this way, the selective etching layer is removed and the mesa is penetrated in the connecting region 320 except the semiconductor buried taper portion 323, and the selective etching layer having a desired width is left in the EA modulator 330.

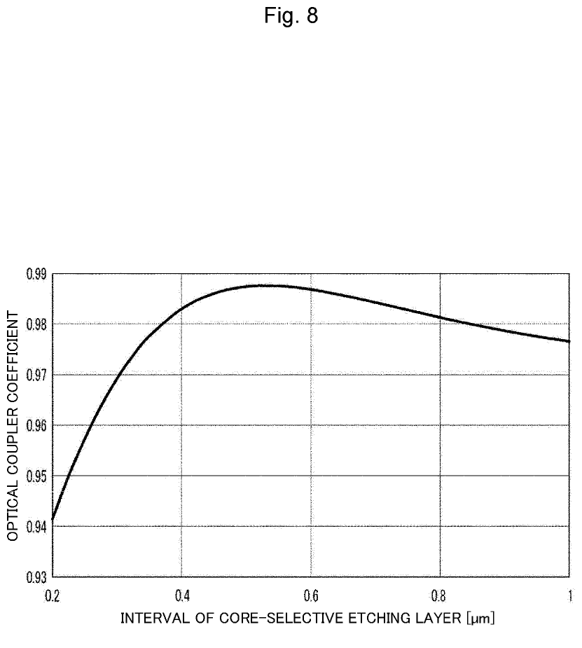

FIG. 8 shows dependence of the optical coupling coefficient on an interval between the waveguide core and the selective etching layer in the EA modulator of the embodiment 3. When the width of the high-mesa structure is 1.2 μm, the optical coupling coefficient is shown, which varies depending on the interval between the waveguide core and the selective etching layer, that is, the thicknesses of the lower cladding layer 327 and the upper cladding layer 328. When the interval is 550 nm, the optical coupling coefficient between the waveguide 312 of the DFB laser 310 and the waveguide 332 of the EA modulator 330 is 0.988 at a maximum. Therefore, according to the configuration of the connecting region 320 of the embodiment 3, the coupling efficiency between the DFB laser 310 and the EA modulator 330 can be improved.

As described above, according to the present embodiment, the EA modulator can be shortened in length and widened in band by the structure in which the optical confinement factor of the EA modulator is increased. In addition, the coupling efficiency between the semiconductor laser and the EA modulator can be improved in the connecting region between the semiconductor laser and the EA modulator integrated monolithically, by applying a semiconductor buried taper portion and introducing the structure similar to the EA modulator. Thus, the junction loss in the optical connection between the different kinds of waveguides is reduced, and the optical transmitter that can be operated at a high speed and has a high output can be realized.

1. An optical modulator having a high-mesa structure made of an InP-based materials comprising:
a waveguide core having a multi quantum well structure;
a lower selective etching layer inserted into a lower cladding at an interval from the waveguide core; and
an upper selective etching layer inserted into an upper cladding at an interval from the waveguide core,
wherein width of the lower selective etching layer and the upper selective etching layer are narrower than a mesa width of the high-mesa structure.

2. The optical modulator according to claim 1, wherein the multi quantum well structure is made of InGaAsP-based materials, the lower selective etching layer and the upper selective etching layer are made of an InGaAlAs material.

3. The optical modulator according to claim 1, wherein
the interval between the lower selective etching layer and the waveguide core and the interval between the upper selective etching layer and the waveguide core are in a range of 0.01 to 1 μm, thicknesses of the lower selective etching layer and the upper selective etching layer are in a range of 0.2 to 1 μm, and widths of the lower selective etching layer and the upper selective etching layer are in a range of 30% to 50% of the mesa width of the high-mesa structure.

4. An optical transmitter monolithically integrated by:
a buried semiconductor laser filled with insulating InP;
an optical modulator having a high-mesa structure made of an InP-based materials; and
a connecting region connecting a waveguide core of the buried semiconductor laser and a waveguide core of the optical modulator,
wherein the connecting region is made of a bulk waveguide composed of an InGaAsP-based material, and comprises a semiconductor buried taper portion that is a connecting portion with the waveguide core of the buried semiconductor laser, wherein the semiconductor buried taper portion is filled with the insulating InP at a connecting end face with the waveguide core of the buried semiconductor laser, and filled with a buried layer that buries the waveguide core of the optical modulator at a connecting end face with the waveguide core of the optical modulator, wherein a tapered buried interface forms 45 degrees with respect to an optical axis direction of the bulk waveguide.

5. The optical transmitter according to claim 4, wherein the bulk waveguide is composed of an InGaAsP-based material, the buried layer is composed of a polymeric material.

6. The optical transmitter according to claim 5, wherein the connecting region excluding the semiconductor buried taper portion comprises: a layer composed of the polymeric material inserted into a lower cladding at an interval from the bulk waveguide; and a layer composed of the polymeric material inserted into an upper cladding at an interval from the bulk waveguide.
